(19) United States
(12) Patent Application Publication
(10) Pub. No.: US 2007/0018688 A1
(43) Pub. Date: Jan. 25, 2007

(54) Digital Logic Unit

(76) Inventors: Dieter Merk, Freising (DE); Markus Koesler, Landshut (DE)

Correspondence Address: TEXAS INSTRUMENTS INCORPORATED, P O BOX 655474, M/S 3999, DALLAS, TX, 75265, US

(21) Appl. No.: 11/457,929

(22) Filed: Jul. 17, 2006

(30) Foreign Application Priority Data
Jul. 15, 2005 (DE) 10 2005 033 270.6

(51) Int. Cl. H03K 19/00

(52) U.S. Cl. 326/93

(57) ABSTRACT

The invention provides a digital logic driven by a master clock signal and includes logic circuitry with processing stages capable of performing logic operations within a fraction of the period of the master clock signal. Furthermore, the digital logic unit comprises clock distribution means that supple clock signals to the logic circuitry, the clock signals being derived from the master clock at mutually shifted phases.

The invention relates to a digital logic unit driven by a master clock signal.

### BACKGROUND

Digital integrated circuits (ICs), in particular central processing unit (CPU) cores, use small transistor dimensions to achieve high computing power at an increased clock speed. This leads to a reduced die area needed for the same functionality, or, in other words, more features can be implemented on the same die area.

The transistors on the die area, however, produce a great deal of heat, which cannot easily be removed. Furthermore, power consumption becomes an issue, because a lot of applications are battery-powered, resulting in a limited running time of the whole device.

### SUMMARY

The invention provides a digital logic unit driven by a master clock signal and includes logic circuitry with processing stages capable of performing logic operations within a fraction of the period of the master clock signal. Furthermore, the digital logic unit comprises clock distribution means that supply distributed clock signals to the logic circuitry, the distributed clock signals being derived from the master clock at mutually shifted phases.

This approach optimally uses the capability of certain processing stages within the digital logic unit to perform basic logic operations very rapidly compared to the duration of a master clock period. The distributed clock signals fake a much higher clock frequency by just providing more clock signal edges within a period of the master clock signal. Thus, the performance of the logic unit, at least for certain logic operations, can be dramatically improved without increasing the frequency of the master clock, and thus without an increase in current consumption.

Another advantage of this approach is that the digital logic consumes energy in a more efficient way leading to an increased running time, e.g., of a battery-powered application, or to a higher performance with the same amount of energy.

Furthermore, the master clock signal does not need to be of high frequency for the whole digital logic unit in case only a part of the unit requires a high clock speed to realize the necessary computation power. The distributed clock signals deliver more “clock edges” to those parts of the unit with a need for a high clock speed, whereas the master clock signal is set to an amount of speed just sufficiently fast for the remaining digital logic unit.

Hence, it is possible to increase the speed of a particular logic operation without the need to increase the (master) clock frequency. Furthermore, it is advantageous that only an active processing stage receives a clock edge for processing while the other stages are in an idle state. In other words, the respective stage is only clocked at a time when it is needed.

Yet another advantage of the described device is the increased processing speed for parts of the logic unit, which are capable of and have a demand for high processing power. This allows data to be fed through the chain of register banks faster than it would be possible, if the registers were all to use the same clock. Hence, for the same data processing time (i.e. the time from data input to data output) this approach is much faster than a pure synchronous design.

As an embodiment, the digital logic unit can be a digital processor unit.

In an embodiment, the distributed clock signals are derived from the master clock signal at substantially the same master clock frequency. This leads to phase-shifted signals of substantially the same frequency.

In a further embodiment, the digital logic unit comprises a multiplexing arrangement selectively switching the distributed clock signals to successive processing stages of the logic circuitry. Hence, the multiplexing unit can efficiently control the processing stages dependent on their respective processing capability.

In an advanced embodiment the successive processing stages each have an input register and the distributed clock signals are applied to the clock inputs of the input registers. This allows phase-shifted processing of the respective processing stages within on master clock period. Dependent on the performance of a processing stage, the successive processing stage can be triggered (via its input register) by a phase shifted clock within, e.g., a short delay after the previous (distributed) clock signal. This leads to a fast and efficient way to utilize the computation speed of the processing stages, further leading to a significantly better overall performance of the digital logic unit.

In yet a further embodiment, a last one of the successive processing stages is followed by a result register clocked by one of the distributed clock signals.

furthermore, the distributed clock signal applied to the result register can be in-phase with the master clock signal. Hence, the whole processing of the processing stages between the input and the result registers is completed within one (or more) period(s) of a

In addition, the distributed clock signals can be taken from taps of an on-die ring oscillator. In many cases, digital logic comprise such oscillators with can be used by tapping the required clock signals at the outputs of successive inverter stages. Hence, there is no need for a separate generation of the distributed clock signals.

According to an advanced embodiment, a (complex) processing operation is completed by successive processing stages within a single period of the master clock signal. Alternatively, the (complex) processing operation can be completed by successive processing stages in plural periods of the master clock signal.

In a further embodiment, the distributed clock signals can comprise dynamically varied phase shifting ratios. This allows to efficiently use the computation power, e.g., dependent on the available energy, e.g., battery power. It is also possible to compute operations of high priority at a faster pace than operations considered less prior. It is further achievable to avoid heating-up of the unit by dynamically lowering the computation speed by enlarging the phase-shifts of the, e.g., rising edges triggering the respective registers of the fast (but hot) processing stages.

As an additional advantage, integrated circuits absorbing less heat have less leakage than hot circuits. This, however, leads to a reduced energy consumption of the device.

### BRIEF DESCRIPTION OF THE DRAWINGS

Example embodiments of the invention are described with reference to the accompanying figures, wherein:

FIG. 1 is a schematic block diagram of a clock generator generating mutually phase shifted clock signals from a master clock signal;

FIG. 2 is a signal chart of the master clock signal and the mutually phase shifted clock signals produced by the generator of FIG. 1;

FIG. 3 is a schematic illustration of sequential data processing stages, each having an input register and each being controlled by a separate clock signal;

FIG. 4 is a ring oscillator producing mutually phase shifted clock signals fed into a multiplexer structure, which is used to control a logic unit;

FIG. 5 is a multiplier structure conventionally using a master clock signal;

FIG. 6 is a signal chart pertaining to the multiplier structure according to FIG. 5;

FIG. 7 is a multiplier structure using a master clock signal and three phase shifted clock signals; and

FIG. 8 is a signal chart illustrating operation of the multiplier structure according to FIG. 7.

### DETAILED DESCRIPTION OF THE EMBODIMENTS

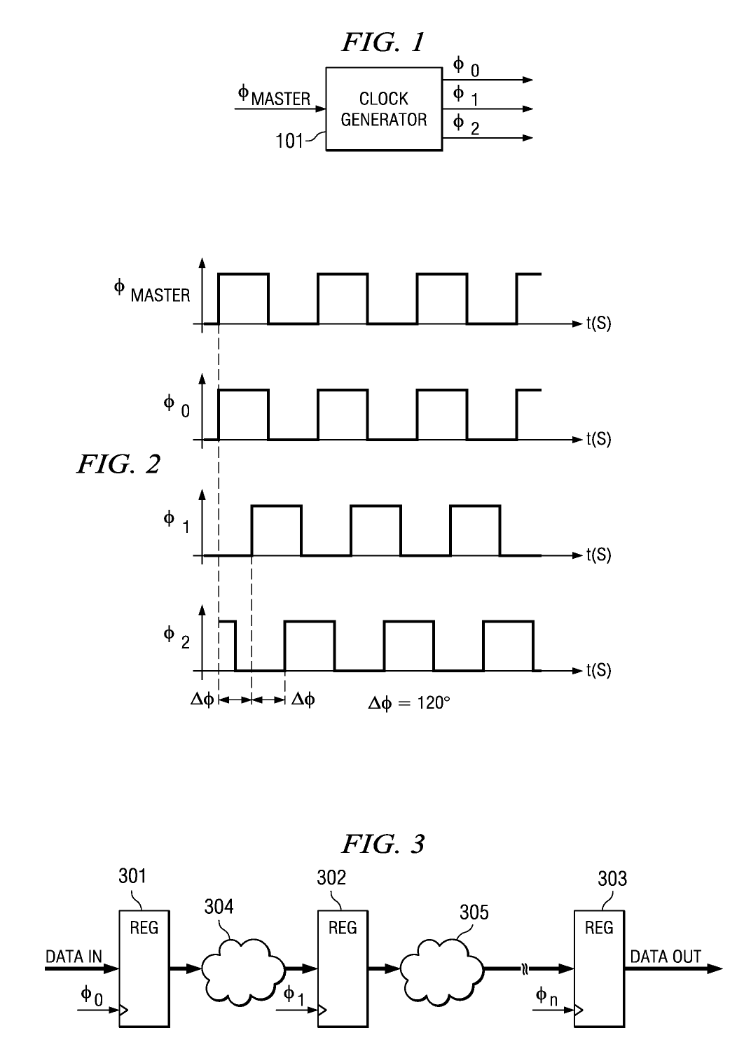

FIG. 1 shows a clock generator 101 receiving a master clock signal Φₘₐₛₜₑᵣ and providing three clock signals Φ₀, Φ₁, and Φ₂ at mutually shifted phases. The related signal chart illustrating the clock signals Φₘₐₛₜₑᵣ, Φ₀, Φ₁ and Φ₂ is shown in FIG. 2. All clock signals have the same frequency, the clock signal Φ₀ has the same phase as the master clock signal Φₘₐₛₜₑᵣ, the clock signal Φ₁ has a phase shift (compared to the clock signal Φ₀) of ΔΦ=120° and the clock signal Φ₂ is phase shifted by another ΔΦ=120° compared to the clock signal Φ₁. As used herein, the term “distributed clock signals” means any clock signal derived from the master clock signal, including the master clock signal itself.

This implementation makes it possible to generate more clock edges (within the period of the master clock signal) for those parts of a digital logic unit which are capable of operating at a higher clock speed than the master clock.

Phase shifted clocks can be used in digital designs with multistage register banks and processing stages to deliver a clock edge at a time to a register when the previous processing block (stage) has finished its computation without the disadvantage to clock the previous register again. FIG. 3 shows a sequence of processing stages comprising registers 301 and 303 and data processing blocks 304 and 305. Clock signals Φ₀, Φ₁, Φn are applied to register 301, 302 and 303, respectively. Register 301 has an input “Data in” and register 303 has an output “Data out”. Each register 301 to 303 is clocked by a different one of the distributed clock signals Φ₀ to Φn with mutually shifted phases as shown in FIG. 2. Hence, the consumed power for one processing cycle can be reduced, because only the actual active processing stage receives a clock edge by the respective clock signal whereas the other stages are in an idle state.

To comply with the implementation as described, the digital cells of the digital logic unit which are clocked by the master clock signal and the derived clock signals need a higher maximum processing speed than the master clock speed. For example, if 3 phase-shifted clocks are used at a master clock frequency of 200 MHz, the cell must be capable of handling 3 times the master clock frequency, i.e. at least 600 MHz:
f_{cell}_max>n*f_{clock}
with
f_{cell}_max maximum frequency that has to be supported by the cell;
f_{clock} master clock frequency;
n number of phase-shifted clock signals.

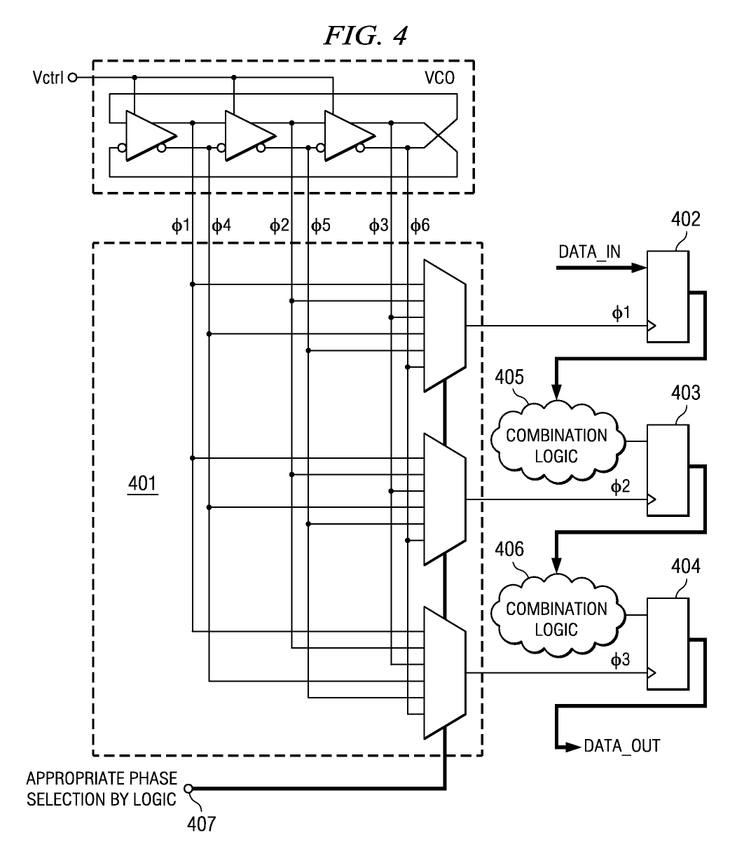

FIG. 4 shows a voltage controlled oscillator VCO implemented as a ring oscillator. Such a ring oscillator can be found in most microprocessor systems as a part of a multiplying phase locked loop (PLL). Phase shifted signals Φ₀ to Φ₆ can be taken from taps of the ring oscillator. In the example shown in FIG. 4, a differential 3-stage ring oscillator allows to derive 6 constant phases in equal distances of 60 degrees. The different phases, i.e. phase shifted signals Φ₀ to Φ₆ can be applied via a multiplexer 401 to registers 402 to 404. The multiplexer 401 is controlled by a logic (not shown) via signal 407. Data to be processed “Data_in” is input to register 402 which is triggered by the clock signal Φ₁. The output of register 402 is fed to a combination logic 405 and then to the register 403, which is clocked by the clock signal Φ₂. The output of register 403 is forwarded to a combination logic 406 and further to the register 404, which is triggered by the clock signal Φ₃. The multiplexer applies the clock signals Φ₁, Φ₂, Φ₃ to the respective registers 402 to 404. This design is adaptive to the complexity of the combination logic, i.e. fast processing by the respective combination logic 405 and 406 can be utilized by applying the subsequent phase-shifted clock signals to subsequent processing stages in order to dynamically execute several operations till within the duration of one master clock cycle.

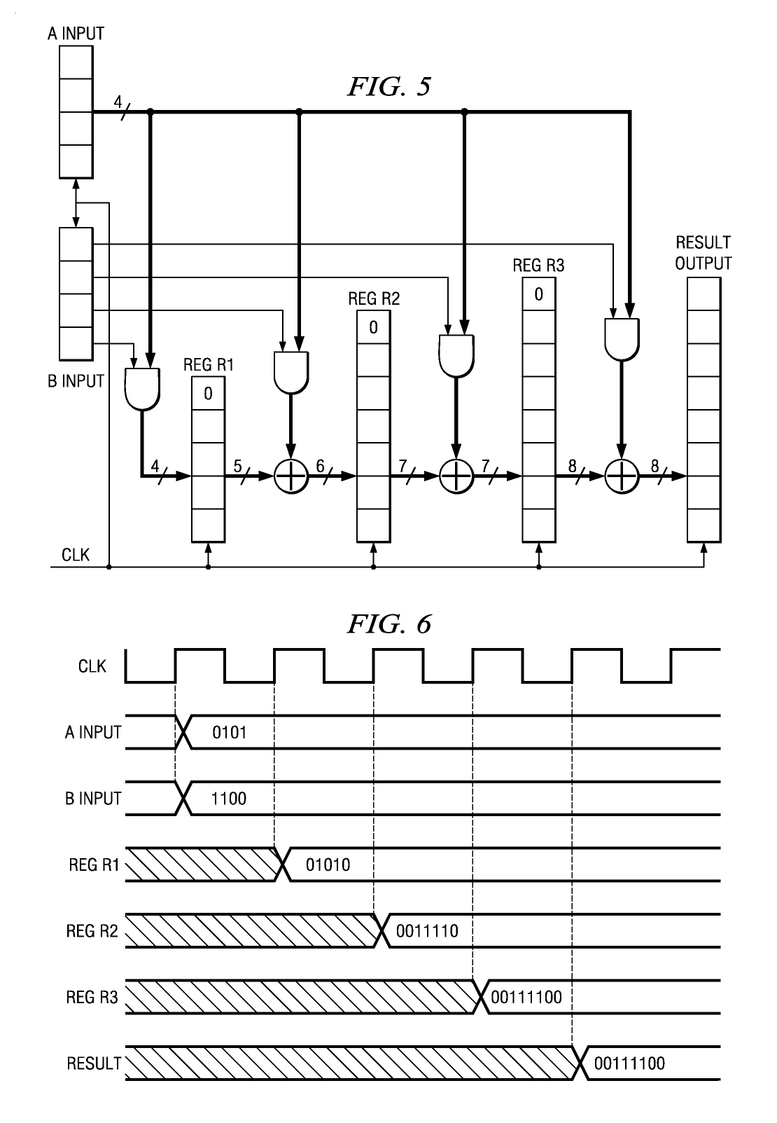

FIG. 5 shows a multiplier structure triggered by a master clock signal CLK.

This structure multiplies two 4-bit values A and B thereby producing an 8-bit result value “RESULT OUTPUT”. For the calculation 4 register stages “REG R1”, “REG R2”. “REG R3” and “RESULT OUTPUT” are used, each storing the results of each addition needed for performing a multiplication.

If the value for A is “0101” and the value for B is “1100”, the multiplication will be processed as follows: A is combined with the MSB (most significant bit) of B by an AND-gate, the “01010” is stored in register “REG R1”. The next AND-gate produces “0101” which is added to “01010” resulting in “0011110” stored in register REG R2”. The next two stages added “0000” resulting in the 8-bit value “0011 1100”.

All registers are clocked with the same master clock signal CLK. FIG. 6 shows the signal chart of the multiplier structure during multiplication of the values A and B. The multiplication as described requires 5 clock-cycles of the master clock signal CLK.

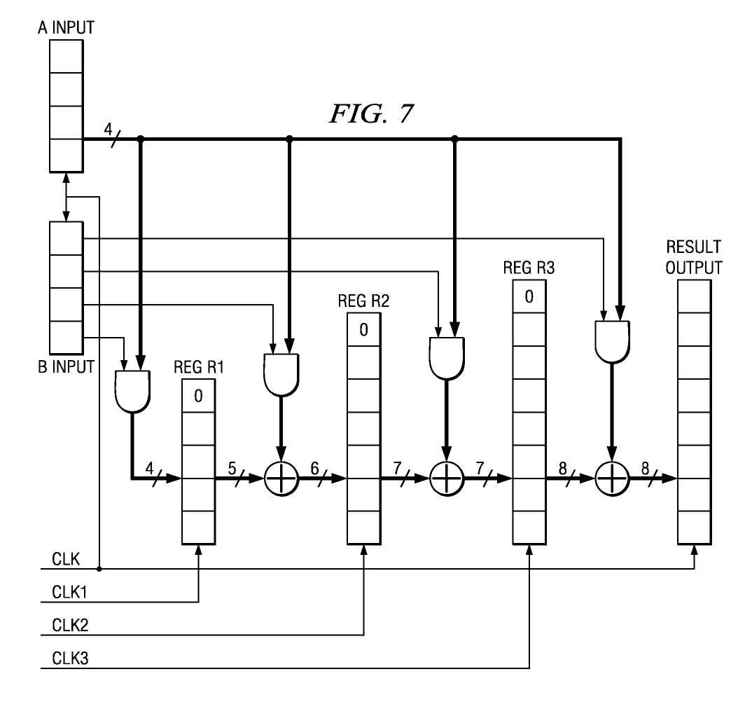

FIG. 7 shows a generally similar multiplier as FIG. 5. This multiplier, however, receives a master clock signal CLK is 90° phase-shifted, CLK2 is 180° phase-shifted and CLK3 is 270° phase-shifted compared to the master clock signal CLK.

The signal CLK1 is applied to register “REG R1”, the signal CLK2 is applied to register “reg. R2” and the signal CLK3 is applied to register “REG R3”. The master clock signal CLK is applied to the input stages and to the result output register of the multiplier.

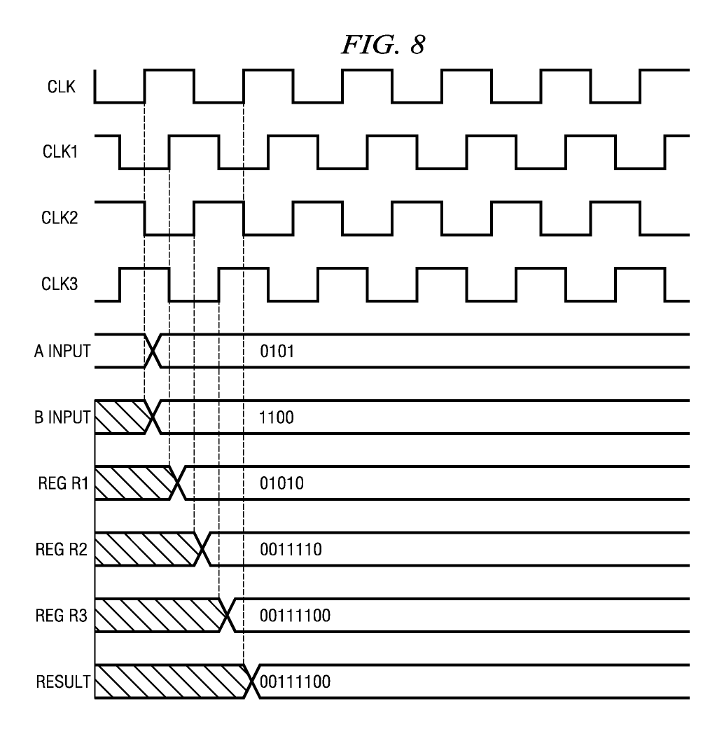

FIG. 8 shows a signal chart similar to FIG. 6, but clearly evidencing a reduced processing time. The result is available in the result register one master clock cycle after the values for A and B have been loaded into the input registers. The hardware implementation of FIG. 7 is the same as that of FIG. 5, except that the clocks for each register are distributed within each master clock period instead of only using just the master clock signal.

In the example, this leads to a reduced power consumption by a factor 4 for the multiplier structure, because each register needs to be clocked only once until the result is available. In addition, the result is available 4 times faster than in the implementation with only just the master clock signal.

As an alternative to the implementation of FIG. 7, it is also possible to allow the multiplication process to last, e.g., 2 master clock cycles. This could be deemed useful if the combination logic is not fast enough to cope with the distributed clock signals available in a single master clock period.

Furthermore, it is possible to allow the phase-shift ratio to be dynamically changed during a running application. Thus, the processing power required at a given moment could be adapted.

As an example, the frequency of the master clock signal if fcycle=100 MHz (t_{cycle}=10 ns). In a synchronous design, each stage receives a clock signal even if 20 there is no need for a clock signal. The whole power consumed by such a multiplier is defined by P_{sync}.

Still referring to the example, the approach provided with this invention allows not only to reduce the power needed for the requested operation by the factor 4, but also to reduce the time needed for the operation by the same factor in case 4 mutually phase-shifted clock signals are applied as the distributed clock signals.

Comparing the approach provided with the invention with conventional approaches, shows the following disadvantages which are overcome by the solution provided herewith:

With the use of gated clock signals for each stage, the power consumption can be reduced by a factor 4 as only the stage doing the calculation receives a clock signal, whereas the other stages do not receive anything. Hence, the consumed power of the gated multiplier can be defined as P_{gated}≈P_{sync}/4, whereas t_{gated}=t_{sync}, because 4 clock cycles are still needed to multiply A and B. In addition, a state machine will be required for handling the gating of the clock signals. Another possibility to reduce power is to use only one register stage with a feedback. All 4 clock cycles needed for executing the multiplication always use the same register stage. This helps to reduce the size of the die needed, the power needed is similar to the gated version above, but there is no advantage in the time required (still 4 clock cycles needed).

What is claimed is:

1. A digital logic unit driven by as master clock signal and
including logic circuitry with processing stages capable of performing logic operations within a fraction of the period of the master clock signal, and
including clock distribution means that supply to the logic circuitry distributed clock signals derived from the master clock at mutually shifted phases.

2. The digital logic unit of claim 1, wherein the distributed clock signals are derived from the master clock signal at substantially the same master clock frequency.

3. The digital logic unit of claim 1, comprising a multiplexing arrangement selectively switching the distributed clock signals to successive processing stages of the logic circuitry.

4. The digital logic unit of claim 3, wherein the successive processing stages each have an input register and the distributed clock signals are applied to the clock inputs of the input registers.

5. The digital logic unit of claim 4, wherein a last one of the successive processing stages is followed by a result register clocked by one of the distributed clock signals.

6. The digital logic unit of claim 5, wherein the distributed clock signal applied to the result register is in-phase with the master clock signal.

7. The digital logic unit of claim 1, wherein the distributed clock signals are taken from taps of an on-die ring oscillator.

8. The digital logic unit of claim 1, wherein a processing operation is completed by successive processing stages within a single period of the master clock signal.

9. The digital logic unit of claim 1, wherein a processing operation is completed by successive processing stages in plural periods of the master clock signal.

10. The digital logic unit of claim 1, wherein the distributed clock signals have dynamically varied phase shifting ratios.

11. The digital logic unit of claim 1, wherein the logic unit is a processor unit.
